(19) United States
(12) Patent Application Publication
(10) Pub. No.: US 2022/0254700 A1
(43) Pub. Date: Aug. 11, 2022

(54) PACKAGED POWER SEMICONDUCTOR DEVICE

(71) Applicant: POWER MASTER SEMICONDUCTOR CO., LTD., Bucheon-si (KR)

(72) Inventors: In-Suk Kim, Bucheon-si (KR); Ki-Myung Yoon, Bucheon-si (KR)

(21) Appl. No.: 17/320,363

(22) Filed: May 14, 2021

(30) Foreign Application Priority Data
Feb. 5, 2021 (KR) 10-2021-0016966

(51) Int. Cl. H01L 23/373; H01L 23/495; H01L 23/00; H01L 23/31

(52) U.S. Cl. CPC H01L 23/3735; H01L 23/49524; H01L 2224/48175; H01L 24/48; H01L 23/315; H01L 23/49548

(57) ABSTRACT

A packaged power semiconductor device is provided. The packaged power semiconductor device may include: a direct bonded copper (DBC) substrate configured to include an upper surface in which an upper region, a middle region, and a lower region are defined; a metal tab formed to be directly connected to the upper surface in the upper region; a first lead formed to be directly connected to the upper surface in the lower region; and a semiconductor chip formed on the upper surface in the middle region.

### CROSS-REFERENCE TO RELATED APPLICATION

This application claims priority to and benefits of Korean Patent Application No. 10-2021-0016966, filed in the Korean Intellectual Property Office on Feb. 5, 2021, the entire contents of which are incorporated herein by reference.

### BACKGROUND OF THE DISCLOSURE

### (a) Field of the Disclosure

The present disclosure relates to a packaged power semiconductor device.

### (b) Description of the Related Art

A power semiconductor device such as a silicon controlled rectifier (SCR), an insulated gate bipolar transistor (IGBT), a silicon carbide (SiC), a field effect transistor (FET), a metal oxide semiconductor field effect transistor (MOSET), a power rectifier, and a power regulator operate at a relatively high voltage, but is assembled in a package that is not electrically isolated. In general, metal tabs forming a rear surface of the package are electrically connected to a semiconductor chip (or semiconductor die), and thus a potential of the rear surface of the package may be the same as a potential of the semiconductor chip.

Such a packaged power semiconductor device is designed to operate at a relatively high voltage, unlike a semiconductor device such as a memory. Accordingly, when the potential at the rear surface of the packaged power semiconductor device is high voltage, there is a risk of damaging other circuit components. In addition, the packaged power semiconductor device often operates in a harsh environment with a high usage temperature and a long usage time, and thus an effective heat dissipation method is required.

The above information disclosed in this Background section is only for enhancement of understanding of the background of the disclosure, and therefore, it may contain information that does not form the prior art that is already known in this country to a person of ordinary skill in the art.

### SUMMARY OF THE DISCLOSURE

The present disclosure has been made in an effort to provide a packaged power semiconductor device having high operation stability and heat dissipation effect.

An embodiment of the present disclosure provides a packaged power semiconductor device including: a direct bonded copper (DBC) substrate configured to include an upper surface in which an upper region, a middle region, and a lower region are defined; a metal tab formed to be directly connected to the upper surface in the upper region; a first lead formed to be directly connected to the upper surface in the lower region; and a semiconductor chip formed on the upper surface in the middle region.

The packaged power semiconductor device may further include a second lead not connected to the upper surface and formed to be connected to the semiconductor chip by a wire.

Shapes of the first lead and the second lead may be different from each other.

The packaged power semiconductor device may further include a third lead not connected to the upper surface and formed to be connected to the semiconductor chip by a metal clip.

Shapes of the first lead and the third lead may be different from each other.

The packaged power semiconductor device may further include an encapsulation unit configured to encapsulate the semiconductor chip, and a lower surface of the DBC substrate may be exposed on a rear surface of the encapsulation unit.

The encapsulation unit has a second through hole having a shape matching a first through hole formed in the metal tab.

An embodiment of the present disclosure provides a packaged power semiconductor device including: a metal tab; a DBC substrate formed on the metal tab; a semiconductor chip formed on the DBC substrate; and a lead formed to be electrically connected to the semiconductor chip.

The DBC substrate may include a first metal layer, a ceramic layer, and a second metal layer, the semiconductor chip may be formed to be directly connected to an upper surface of the first metal layer, and the metal tab may be formed to be directly connected to a lower surface of the second metal layer.

The lead may be electrically connected to the semiconductor chip through a wire or a metal clip, or the lead may be directly connected to an upper surface of the DBC substrate to be electrically connected to the semiconductor chip.

The packaged power semiconductor device may further include an encapsulation unit configured to encapsulate the semiconductor chip, and a lower surface of the metal tab may be exposed on a rear surface of the encapsulation unit.

The encapsulation unit may have a second through hole having a shape matching a first through hole formed in the metal tab.

The packaged power semiconductor device according to the embodiments of the present disclosure may have high operating stability and an excellent heat dissipation effect even in an environment operating at a high voltage.

### BRIEF DESCRIPTION OF THE DRAWINGS

FIG. 1 to FIG. 3 illustrate views for describing a packaged power semiconductor device according to an embodiment of the present disclosure.

FIG. 4 and FIG. 5 illustrate views for describing a packaged power semiconductor device according to an embodiment of the present disclosure.

FIG. 6 to FIG. 9 illustrate views for describing a packaged power semiconductor device according to an embodiment of the present disclosure.

FIG. 10 to FIG. 13 illustrate views for describing a packaged power semiconductor device according to an embodiment of the present disclosure.

### DETAILED DESCRIPTION OF THE EMBODIMENTS

Hereinafter, the present disclosure will be described more fully with reference to the accompanying drawings, in which embodiments of the disclosure are shown. As those skilled in the art would realize, the described embodiments may be modified in various different ways, all without departing from the spirit or scope of the present disclosure. Accordingly, the drawings and description are to be regarded as illustrative in nature and not restrictive. Like reference numerals designate like elements throughout the specification. In addition, throughout the specification and claims, unless explicitly described to the contrary, the word “comprise” and variations such as “comprises” or “comprising” will be understood to imply the inclusion of stated elements but not the exclusion of any other elements.

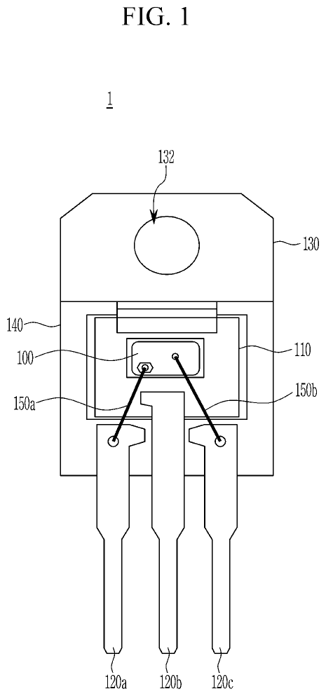

FIG. 1 to FIG. 3 illustrate views for describing a packaged power semiconductor device according to an embodiment of the present disclosure.

Referring to FIG. 1 to FIG. 3, the packaged power semiconductor device according to the embodiment of the present disclosure includes a semiconductor chip 100, a DBC substrate 110, leads 120, a metal tab 130, and an encapsulation unit 140. The lead 120 may be implemented as a plurality of leads 120a, 120b, and 120c depending on a specific implementation purpose, and in this specification, for convenience of description, when referring to a lead as a conceptual element, reference is made to “120”, and when referring to an example implementation element, the letters ‘a’, ‘b’, and ‘c’ are added after “120” for reference.

The semiconductor chip 100 may be a power semiconductor device. Examples of the power semiconductor device may include a silicon controlled rectifier (SCR), an insulated gate bipolar transistor (IGBT), a silicon carbide (SiC), a field effect transistor (FET), a metal oxide semiconductor field effect transistor (MOSET), a power rectifier, and a power regulator, and particularly, a power MOSFET device may be used, and it may have a double-diffused metal oxide semiconductor (DMOS) structure due to a high voltage and high current operation unlike a general MOSFET. However, the scope of the present disclosure is not limited to these examples.

The DBC substrate 110 may include a first metal layer 112, a second metal layer 116, and a ceramic layer 114 formed between the first metal layer 112 and the second metal layer 116. The first metal layer 112 and the second metal layer 33 may include copper (Cu), but the scope of the present disclosure is not limited thereto.

Three areas may be defined on an upper surface of the DBC substrate 110. Herein, the upper surface may be an upper surface of the first metal layer 112. The three regions may include an upper region to which the metal tab 130 is connected, an intermediate region where the semiconductor chip 100 is formed, and a lower region to which the leads 120a, 120b, and 120c are connected, based on FIG. 1. In the three regions, a detailed structure in which the metal tab 130, the semiconductor chip 100, and the leads 120a, 120b, and 120c are connected to the DBC substrate 110 will be described later.

The lead 120, which is for transmitting an electric signal between the semiconductor chip 100 and an external circuit of the packaged power semiconductor device 1, may be formed of a metal to connect the semiconductor chip 100 and the external circuit. That is, the lead 120 may be electrically connected to the semiconductor chip 100. However, as a method for connecting the lead 120 and the semiconductor chip 100, different methods may be used between the leads 120a, 120b, and 120c.

Specifically, the lead 120b may be directly connected to an upper surface of the DBC substrate 110. In particular, the lead 120b may be directly connected to the upper surface of the DBC substrate 110 in the lower region defined on the upper surface of the DBC substrate 110. The lead 120b and the upper surface of the DBC substrate 110 may be connected through soldering, but the scope of the present disclosure is not limited thereto.

Meanwhile, the leads 120a and 120c may not be connected to the upper surface of the DBC substrate 110. That is, the leads 120a and 120c are formed to be spaced apart from each other in a downward direction of the DBC substrate 110 based on FIG. 1, and may be electrically connected to the semiconductor chip 100 through wires 150a and 150b. In FIG. 1, it is illustrated that the leads 120a and 120c are connected to the semiconductor chip 100 through wires 150a and 150b, but the scope of the present disclosure is not limited thereto, and the connection may be made in a way that is other than using a wire (e.g., via a metal clip).

Further, the leads 120a, 120b, and 120c may be implemented such that all of them are directly connected to the upper surface of the DBC substrate 110, or all of them may not be connected to the upper surface of the DBC substrate 110 and may be implemented such that the semiconductor chip 100 is connected through other connection means (e.g., a wire, a metal clip, etc.), but when some of the leads 120a, 120b, and 120c are directly connected to the upper surface of the DBC substrate 110 and some are not connected to the upper surface of the DBC substrate 110, there is no positional limitation between a lead that is directly connected thereto and a lead that is not connected thereto. That is, there is no limitation that the lead directly connected to the upper surface of the DBC substrate 110 must be positioned at a center of the leads, and may be positioned at a left or right edge or any other position.

In the present embodiment, the leads 120a, 120b, and 120c may all have a same shape, or at least some of them may have different shapes. Specifically, the leads 120a, 120b, and 120c may have a straight line shape, an L-shape, an I-shape, a T-shape (or an inverted L-shape or T-shape), etc., but the scope of the present disclosure is not limited thereto, and the shape of the leads 120 may be determined as an optimized shape depending on a specific connection method between the leads 120 and the semiconductor chip 100.

In addition, the leads 120a, 120b, and 120c may have at least one hole, but the scope of the present disclosure is not limited thereto. In this case, all of the leads 120a, 120b, and 120c may each have a hole, and only some of the leads 120a, 120b, and 120c may have a hole.

The metal tab 130 may have a through hole 132, which may also be referred to as a screw hole, and the metal tab 130 having the through hole 132 facilitates mounting of the packaged power semiconductor device 1 and may function as a terminal or a heat sink when mounted. That is, the metal tab 130 may be electrically connected to the semiconductor chip 100, and particularly, the metal tab 130 may be directly connected to the upper surface of the DBC substrate 110 in the upper surface of the DBC substrate 110, and in an upper region of the upper surface thereof.

The encapsulation unit 140 which constitutes a package body, may protect the semiconductor chip 100 mounted therein, at least a portion of the DBC substrate 110, a portion of the leads 120, and a portion of the metal tab 130. The encapsulation unit 140 is generally made of a plastic material, but the scope of the present disclosure is not limited thereto.

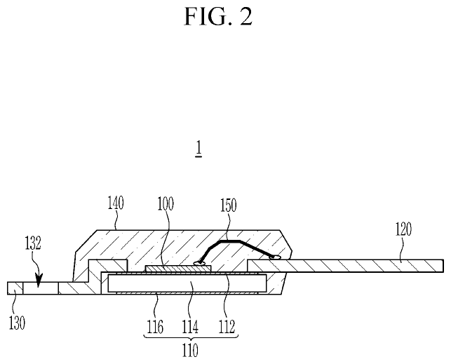

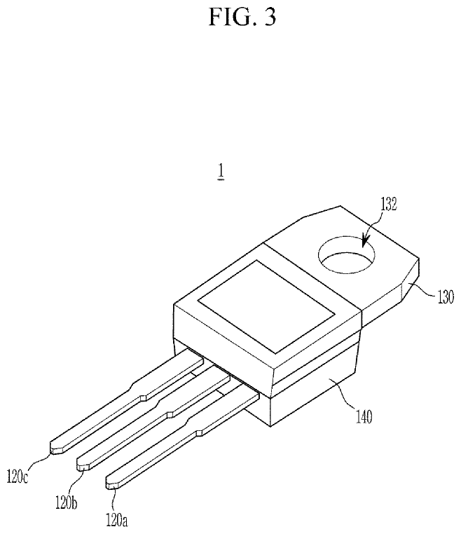

As illustrated FIG. 2 and FIG. 3, the lower surface of the DBC substrate 110 may be exposed in a rear surface of the encapsulation unit 140. Herein, the lower surface may be a lower surface of the second metal layer 116. In addition, a lower surface of the metal tab 130 and the lower surface of the DBC substrate 110 may be formed on a same plane. That is, a portion of the lower surface of the metal tab 130 (protruding from the encapsulation unit 140) is formed on a same plane as the lower surface of the DBC substrate 110, and another portion of the lower surface of the metal tab 130 (included in the encapsulation unit 140) may be formed to be directly connected to the upper surface of the DBC substrate 110.

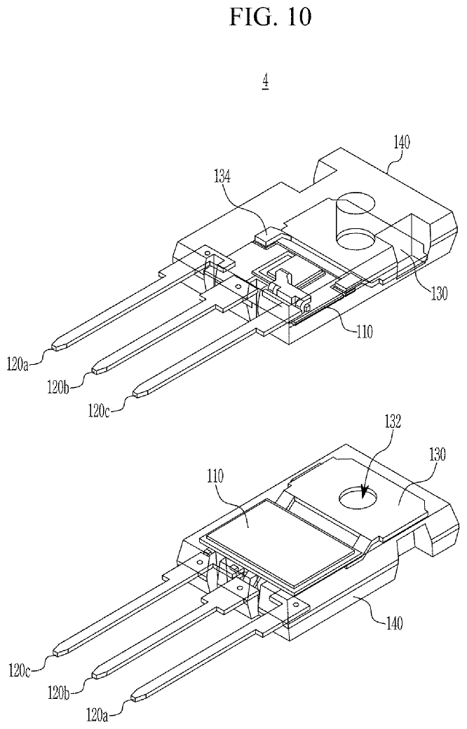

Meanwhile, as illustrated in FIG. 10, the encapsulation unit 140 may include a through hole having a shape matching the through hole 132 formed in the metal tab 130. That is, the encapsulation unit 140 may be formed to cover the entire metal tab 130.

According to the present embodiment, the packaged power semiconductor device 1 having the above-described structure has excellent operation stability and an excellent heat dissipation effect even in an environment of operating at a high voltage. Specifically, the packaged power semiconductor device 1 may have high operation stability due to a structure of the DBC substrate including an insulating layer (ceramic layer) in the middle of the DBC substrate to electrically insulate it from the outside, and may have an excellent heat dissipation effect due to a structure in which the metal layer is formed above and below the ceramic layer of the DBC substrate.

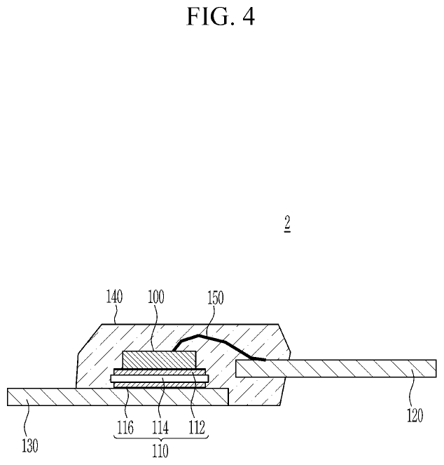

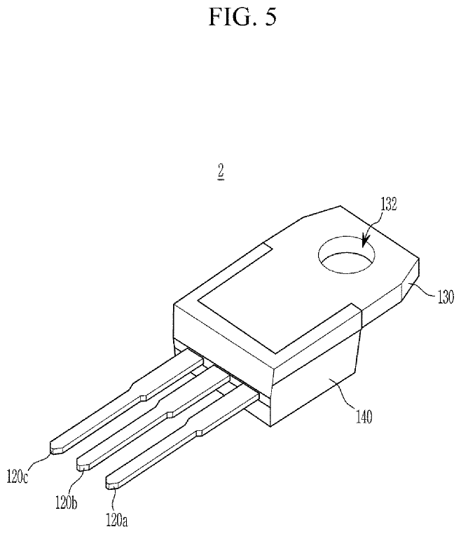

FIG. 4 and FIG. 5 illustrate views for describing a packaged power semiconductor device according to an embodiment of the present disclosure.

Referring to FIG. 4 and FIG. 5, the packaged power semiconductor device 1 according to the embodiment of the present disclosure includes a semiconductor chip 100, a DBC substrate 110, a lead 120, a metal tab 130, and an encapsulation unit 140. The lead 120 may be implemented as a plurality of leads 120a, 120b, and 120c depending on a specific implementation purpose, and in this specification, for convenience of description, when referring to a lead as a conceptual element, reference is made to “120”, and when referring to an example implementation element, the letters ‘a’, ‘b’, and ‘c’ are added after “120” for reference.

Unlike in the packaged power semiconductor device 1 illustrated in FIG. 1 to FIG. 3, the metal tab 130 may be formed such that a side surface thereof extends to have a straight line shape under the DBC substrate 110. In other words, the DBC substrate 110 may be formed on the metal tab 130.

Meanwhile, the semiconductor chip 100 may be formed on the DBC substrate 110. Accordingly, as illustrated in FIG. 4, the packaged power semiconductor device 2 may have a stacked structure in which the metal tab 130, the DBC substrate 110, and the semiconductor chip 100 are sequentially stacked.

The DBC substrate 110 includes a first metal layer 112, a second metal layer 116, and a ceramic layer 114 formed between the first metal layer 112 and the second metal layer 116, and accordingly, in the stacked structure, the semiconductor chip 100 may be formed to be directly connected to the upper surface of the first metal layer 112, and the metal tab 130 may be formed to be directly connected to the lower surface of the second metal layer 116.

In the present embodiment, as illustrated in FIG. 4, a height of a lower surface of the lead 120 may be formed to be higher than that of an upper surface of the metal tab 130. That is, the lower surface of the lead 120 may be formed to be spaced apart from the metal tab 130 by a predetermined distance.

Meanwhile, the lead 120 may not be connected to the upper surface of the DBC substrate 110 and may be formed to be connected through the semiconductor chip 100 and a wire 150, but the scope of the present disclosure is not limited thereto, and similar to the packaged power semiconductor device 1 illustrated in FIG. 1 to FIG. 3, it may be formed to be directly connected to the upper surface of the DBC substrate 110.

In this case, the leads 120a, 120b, and 120c may be implemented such that all of them are directly connected to the upper surface of the DBC substrate 110, or all of them may not be connected to the upper surface of the DBC substrate 110 and may be implemented such that the semiconductor chip 100 is connected through other connection means (e.g., a wire, a metal clip, etc.), but when some of the leads 120a, 120b, and 120c are directly connected to the upper surface of the DBC substrate 110 and some are not connected to the upper surface of the DBC substrate 110, there is no positional limitation between a lead that is directly connected thereto and a lead that is not connected thereto. That is, there is no limitation that the lead directly connected to the upper surface of the DBC substrate 110 must be positioned at a center of the leads, and may be positioned at a left or right edge or any other position.

In the present embodiment, the leads 120a, 120b, and 120c may all have a same shape, or at least some of them may have different shapes. Specifically, the leads 120a, 120b, and 120c may have a straight line shape, an L-shape, an I-shape, a T-shape (or an inverted L-shape or T-shape), etc., but the scope of the present disclosure is not limited thereto, and the shape of the leads 120 may be determined as an optimized shape depending on a specific connection method between the leads 120 and the semiconductor chip 100.

In addition, the leads 120a, 120b, and 120c may have at least one hole, but the scope of the present disclosure is not limited thereto. In this case, all of the leads 120a, 120b, and 120c may each have a hole, and only some of the leads 120a, 120b, and 120c may have a hole.

Meanwhile, as illustrated in FIG. 5, the lower surface of the metal tab 130 may be exposed in the rear surface of the encapsulation unit 140. Accordingly, the rear surface of the encapsulation unit 140 and the lower surface of the metal tab 130 may be formed on a same plane. In particular, as illustrated in FIG. 5, the rear surface of the encapsulation unit 140 may be formed to have a shape surrounding three corners of the metal tab 130 except for a side where a through hole 132 is formed.

Meanwhile, as illustrated in FIG. 10, the encapsulation unit 140 may include a through hole having a shape matching the through hole 132 formed in the metal tab 130. That is, the encapsulation unit 140 may be formed to cover the entire metal tab 130.

According to the present embodiment, the packaged power semiconductor device 2 having the above-described structure has excellent operation stability and an excellent heat dissipation effect even in an environment of operating at a high voltage. Specifically, the packaged power semiconductor device 2 may have high operation stability due to a structure of the DBC substrate including an insulating layer (ceramic layer) in the middle of the DBC substrate to electrically insulate it from the outside, and may have an excellent heat dissipation effect due to a structure in which the metal layer is formed above and below the ceramic layer of the DBC substrate.

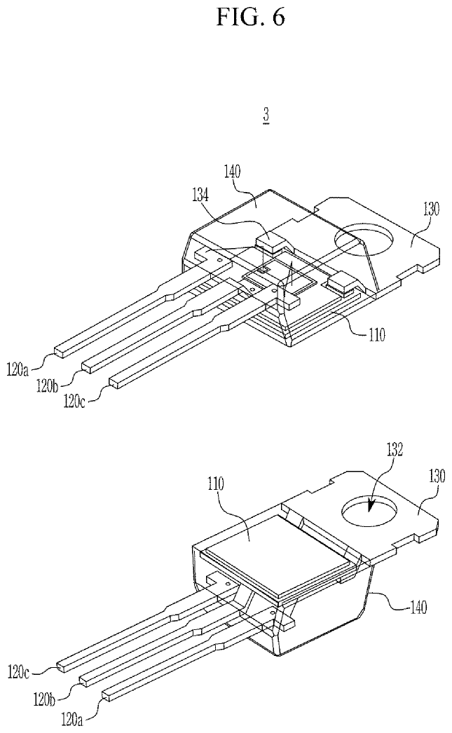

Hereinafter, implementation examples of a packaged power semiconductor device will be described with reference to FIG. 6 to FIG. 13. Of course, the implementation examples illustrated in FIG. 6 to FIG. 13 are only example configurations, and the detailed structures illustrated in FIG. 6 to FIG. 13 do not limit the scope of the present disclosure.

FIG. 6 to FIG. 9 illustrate views for describing a packaged power semiconductor device according to an embodiment of the present disclosure.

Referring to FIG. 6, the metal tab 130 is directly connected to the upper region of the upper surface of the DBC substrate 110. In the metal tab 130, a portion protruding from the encapsulation unit 140 including the through hole 132 is formed to be aligned with a lower surface of the DBC substrate 110 exposed to the rear surface of the sealing portion 140, and a portion 134 connected to the upper surface of the DBC substrate 110 from an inside of the encapsulation unit 140 may be formed to be directly connected to the upper surface of the DBC substrate 110.

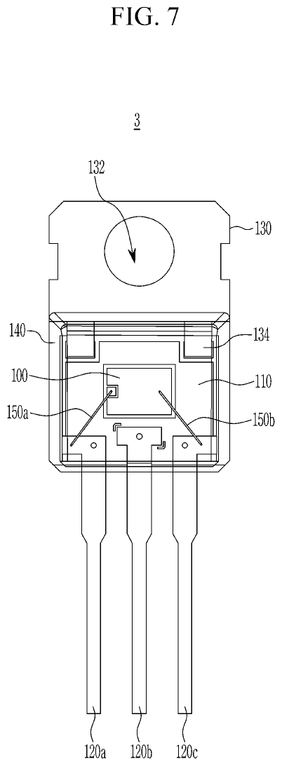

Next, referring to FIG. 7, the lead 120b may be directly connected to the upper surface of the DBC substrate 110 to form an electrical connection with the semiconductor chip 100, and the leads 120a and 120c may not be connected to the upper surface of the DBC substrate 110 and may form electrical connection with the semiconductor chip 100 through wires 150a and 150b. Patterns corresponding to terminals of the semiconductor chip 100 may be formed on the upper surface of the semiconductor chip 100, and as illustrated in FIG. 7, the lead 120a may be connected to a first pattern formed on the upper surface of the semiconductor chip 100 through the wire 150a, and the lead 120c may be connected to a second pattern formed on the upper surface of the semiconductor chip 100 through the wire 150b.

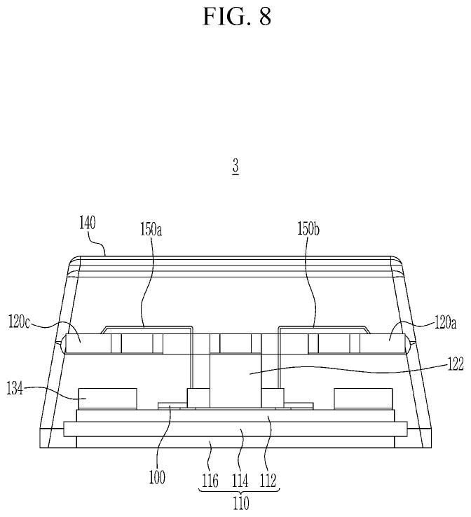

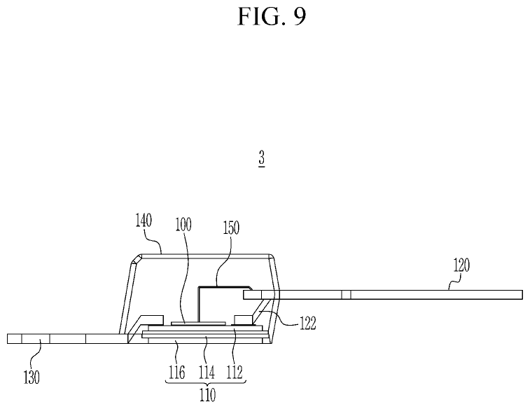

Subsequently, referring to FIG. 8 and FIG. 9, the lead 120b directly connected to the upper surface of the DBC substrate 110 may include a support portion 122 supporting the lead 120b from the upper surface of the DBC substrate 110, and it is possible to match a height of the upper surface of the DBC substrate 110 with that of the leads 120a and 120c that are not connected to each other by forming the support portion 122.

FIG. 10 to FIG. 13 illustrate views for describing a packaged power semiconductor device according to an embodiment of the present disclosure.

Referring to FIG. 10, the metal tab 130 is directly connected to the upper region of the upper surface of the DBC substrate 110, and the entire upper surface of the metal tab 130 may be included in the encapsulation unit 140. Accordingly, the encapsulation unit 140 may be implemented to have a through hole having a shape matching the through hole 132 formed in the metal tab 130. On the other hand, the lower surface of the DBC substrate 110 and the lower surface of the metal tab 130 may be exposed from the rear surface of the encapsulation unit 140, and the lower surface of the DBC substrate 110 and the lower surface of the metal tab 130 may be formed on a same plane.

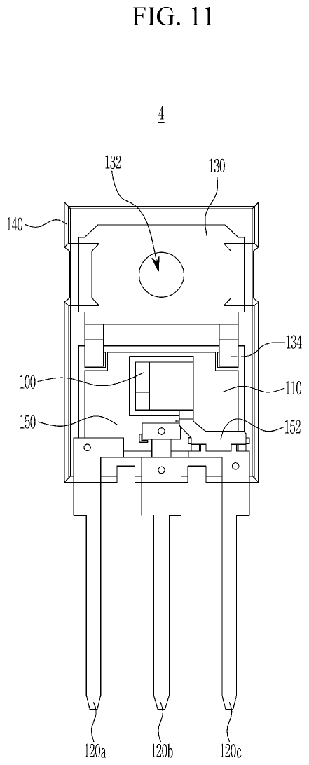

Next, referring to FIG. 11, the lead 120b may be directly connected to the upper surface of the DBC substrate 110 to form electrical connection with the semiconductor chip 100, the lead 120a may not be connected to the upper surface of the DBC substrate 110 and may form electrical connection with the semiconductor chip 100 through the wire 150a, and the lead 120c may not be connected to the upper surface of the DBC substrate 110 and may form electrical connection with the semiconductor chip 100 through the metal clip 152. Patterns corresponding to the terminals of the semiconductor chip 100 may be formed on the upper surface of the semiconductor chip 100, and as illustrated in FIG. 11, the lead 120a may be connected to a first pattern formed on the upper surface of the semiconductor chip 100 through the wire 150a, and the lead 120c may be connected to a second pattern formed on the upper surface of the semiconductor chip 100 through the metal clip 152.

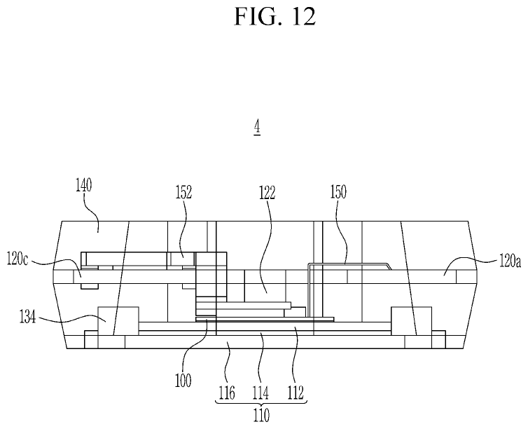

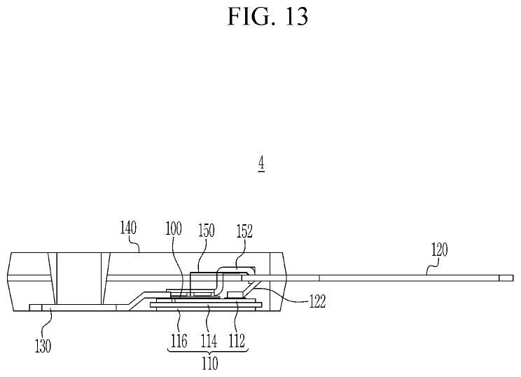

Subsequently, referring to FIG. 12 and FIG. 13, the lead 120b directly connected to the upper surface of the DBC substrate 110 may include a support portion 122 supporting the lead 120b from the upper surface of the DBC substrate 110, and it is possible to match a height of the upper surface of the DBC substrate 110 with that of the leads 120a and 120c that are not connected to each other by forming the support portion 122.

In addition, the metal clip 152 may extend vertically upward from the upper surface of the semiconductor chip 100 and may extend horizontally toward the lead 120 and then may extend vertically downward to fix the lead 120, but the scope of the present disclosure is not limited thereto.

The packaged power semiconductor device according to the embodiments of the present disclosure described so far may have high operating stability and an excellent heat dissipation effect even in an environment of operating at a high voltage.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A packaged power semiconductor device comprising:
a direct bonded copper (DBC) substrate configured to include an upper surface in which an upper region, a middle region, and a lower region are defined;
a metal tab formed to be directly connected to the upper surface in the upper region;
a first lead formed to be directly connected to the upper surface in the lower region; and
a semiconductor chip formed on the upper surface in the middle region.

2. The packaged power semiconductor device of claim 1, further comprising
a second lead not connected to the upper surface and formed to be connected to the semiconductor chip by a wire.

3. The packaged power semiconductor device of claim 2, wherein
shapes of the first lead and the second lead are different from each other.

4. The packaged power semiconductor device of claim 1, further comprising
a third lead not connected to the upper surface and formed to be connected to the semiconductor chip by a metal clip.

5. The packaged power semiconductor device of claim 4, wherein
shapes of the first lead and the third lead are different from each other.

6. The packaged power semiconductor device of claim 1, further comprising
an encapsulation unit configured to encapsulate the semiconductor chip,
wherein a lower surface of the DBC substrate is exposed on a rear surface of the encapsulation unit.

7. The packaged power semiconductor device of claim 6, wherein
the encapsulation unit has a second through hole having a shape matching a first through hole formed in the metal tab.

8. A packaged power semiconductor device comprising:
a metal tab;
a DBC substrate formed on the metal tab;
a semiconductor chip formed on the DBC substrate; and
a lead formed to be electrically connected to the semiconductor chip.

9. The packaged power semiconductor device of claim 8, wherein
the DBC substrate includes a first metal layer, a ceramic layer, and a second metal layer,
the semiconductor chip is formed to be directly connected to an upper surface of the first metal layer, and
the metal tab is formed to be directly connected to a lower surface of the second metal layer.

10. The packaged power semiconductor device of claim 8, wherein
the lead is electrically connected to the semiconductor chip through a wire or a metal clip, or
the lead is directly connected to an upper surface of the DBC substrate to be electrically connected to the semiconductor chip.

11. The packaged power semiconductor device of claim 8, further comprising
an encapsulation unit configured to encapsulate the semiconductor chip,
wherein a lower surface of the metal tab is exposed on a rear surface of the encapsulation unit.

12. The packaged power semiconductor device of claim 11, wherein
the encapsulation unit has a second through hole having a shape matching a first through hole formed in the metal tab.
